(19) United States
(12) Patent Application Publication
(10) Pub. No.: US 2025/0386421 A1
(43) Pub. Date: Dec. 18, 2025

(54) GROUNDING SHIELD SYSTEM FOR ENHANCED THERMAL MANAGEMENT AND ELECTROMAGNETIC INTERFERENCE PROTECTION OF PRINTED CIRCUIT BOARD COMPONENTS

(71) Applicant: PLUME DESIGN, INC., Palo Alto, CA (US)

(72) Inventors: Ming-Tsung SU, Taipei City (TW); Chun Hung LIU, Taipei City (TW)

(21) Appl. No.: 18/745,136

(22) Filed: Jun. 17, 2024

(51) Int. Cl. H05K 1/02; H05K 9/00

(52) U.S. Cl. CPC H05K 1/0215; H05K 1/0203; H05K 9/0024

(57) ABSTRACT

The disclosure is directed to a system configured to protect a chipset and/or central processing unit (CPU) from electrical interference and physical damage, while also addressing heat management issues prevalent in traditional shield case designs. The system includes a heat sink, a grounding shield, and a printed circuit board (PCB), that work in conjunction to protect and remove heat. The heat sink is both electrically and thermally conductive, facilitating heat removal from the PCB, CPU, and/or chipset. The grounding shield, in conjunction with the heat sink, forms a Faraday cage or electrical shielding around the PCB and/or chipset, safeguarding sensitive electronic components from external electromagnetic interference, static discharge, and mechanical damage. The system also improves airflow and efficiency, and transfers heat generated from the PCB, chipset, CPU, and electrical contact to the heat sink. This mitigates the risk of overheating, enhancing the performance and lifespan of the chips.

### FIELD OF THE DISCLOSURE

The present disclosure relates to improvements over shield cases for printed circuit board (PCB) components. More particularly, the disclosure is directed to a system for creating a shield case by electrically coupling a heat sink to a grounding track of a PCB.

### BACKGROUND

There are significant challenges faced by traditional shield case designs for chipsets and central processing units (CPUs). As illustrated in FIG. 1, in these conventional shield cases hot chips are typically enclosed by shield covers 101. These covers are designed to protect the sensitive electronic components from external interference and damage. However, they often inadvertently create a thermal management issue.

Despite some shield covers featuring airflow holes 102 to facilitate heat dissipation, these designs have proven to be insufficient in effectively managing the heat generated by the chips. The primary issue is that the heat produced by the chips is trapped within the shield case, leading to an increase in the internal temperature. This is due to the fact that the shield covers, while allowing some degree of airflow, do not provide an effective thermal-conductive path to pull the heat out from the hot chips.

The trapped heat can lead to a variety of problems. High temperatures can degrade the performance of the chips and shorten their lifespan. In extreme cases, overheating can even cause the chips to fail, leading to system-wide issues.

### BRIEF SUMMARY OF THE DISCLOSURE

To that end, there is a need for a system that not only protects the chips from external interference and damage but also effectively manages the heat they generate. Therefore, there is a need in the art to provide electrical and physical protection to PCB components while simultaneously increasing the rate of heat transfer.

The present disclosure is directed to a system configured to protect a chipset and/or central processing unit (CPU) from electrical interference and physical damage. The system includes various elements such as a heat sink, a grounding shield, and a printed circuit board (PCB). The heat sink is both electrically and thermally conductive, and is configured to remove heat from the PCB, CPU, and/or chipset. The heat sink includes a fan mounting area, heat sink fins, and a fan aperture. The PCB comprises a grounding track and is configured to attach to the heat sink.

The heat sink has a grounding protrusion on one side, designed to align with the grounding track when coupled to the PCB. The grounding protrusion comprises grounding walls that form a shielding perimeter and a sink protrusion within, where the sink protrusion allows for closer proximity to the chipset and/or CPU.

The grounding shield, in conjunction with the heat sink and a grounding track on the PCB, forms a Faraday cage and/or electrical shielding around the PCB and/or chipset, protecting sensitive electronic components from external electromagnetic interference, static discharge, and mechanical damage. The grounding shield includes a grounding rail with electrical contacts that complete a circuit between the grounding protrusions and the grounding track.

The heat sink includes one or more apertures for air flow, and includes a single fan aperture configured to direct airflow around a portion of a shielding perimeter and/or through spaces in the grounding shield in some embodiments. The grounding protrusion is configured not to touch the grounding track when the heat sink is coupled to the PCB, instead forming a gap that is electrically coupled by the grounding shield.

The disclosed system offers several advantages in terms of cost, performance, and assembly process. Cost-wise, the system eliminates the need for a traditional shield case, resulting in substantial cost savings. Additionally, the system does not require a Surface Mount Technology (SMT) process, further reducing manufacturing costs. In terms of performance, the system provides more grounding contact points with a smaller pitch, increasing the efficiency of the grounding system, and improving the overall performance of the chipset and/or CPU.

The enhanced grounding system also provides better protection against electrical interference while simplifying the assembly process by eliminating the need to assemble a shielding cover on the PCB. This not only reduces the time and effort required for assembly but also minimizes the potential for assembly errors. The more efficient assembly process can lead to increased production rates and lower labor costs, further enhancing the overall cost-effectiveness of the system.

### DESCRIPTIONS OF THE DRAWINGS

The features, and advantages of the disclosure will be apparent from the following description of embodiments as illustrated in the accompanying drawings, in which reference characters refer to the same parts throughout the various views. The drawings are not necessarily to scale, emphasis instead being placed upon illustrating principles of the disclosure:

FIG. 1 shows shielding cases of the prior art;

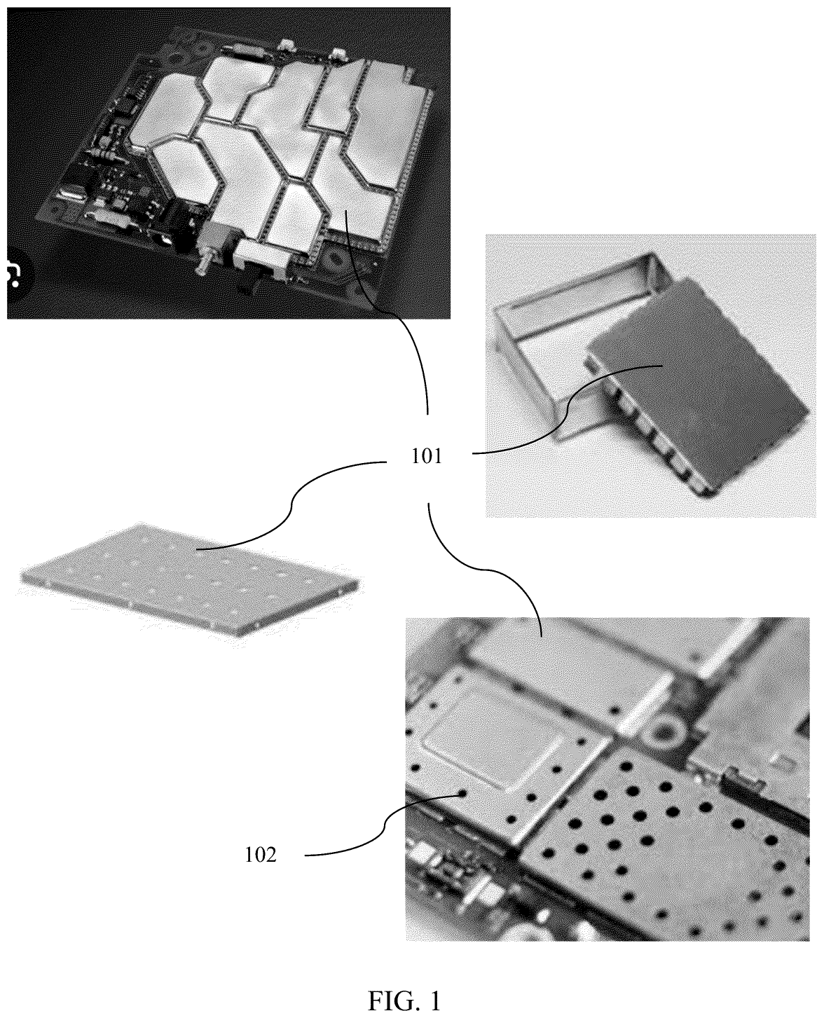

FIG. 2 illustrates an assembled view of the system according to some embodiments of the present disclosure;

FIG. 3 shows the heat sink separated from the printed circuit control board according to some embodiments of the present disclosure;

FIG. 4 depicts a second side of the heat sink according to some embodiments of the present disclosure;

FIG. 5 shows a grounding shield isolated from the rest of the system according to some embodiments of the present disclosure;

FIG. 6 illustrates the grounding shield attached to a second side of the heat sink according to some embodiments of the present disclosure;

FIG. 7 shows a zoomed view of an assembled system in the area of the fan aperture according to some embodiments of the present disclosure;

FIG. 8 shows a sectional view of the system according to some embodiments of the present disclosure;

FIG. 9 shows an isometric sectional view of the assembled system according to some embodiments of the present disclosure; and

FIG. 10 shows a reference number table for elements of the system according to some embodiments of the present disclosure.

### DETAILED DESCRIPTION

The present disclosure relates to a system 200 for protecting a chipset 303 and/or central processing unit 302 (CPU) from electrical interference and physical damage. The non-limiting example provided in this section is provided to teach those of ordinary skill how to make and use the system 200, but the scope of the disclosure is not limited to the following example features according to some embodiments.

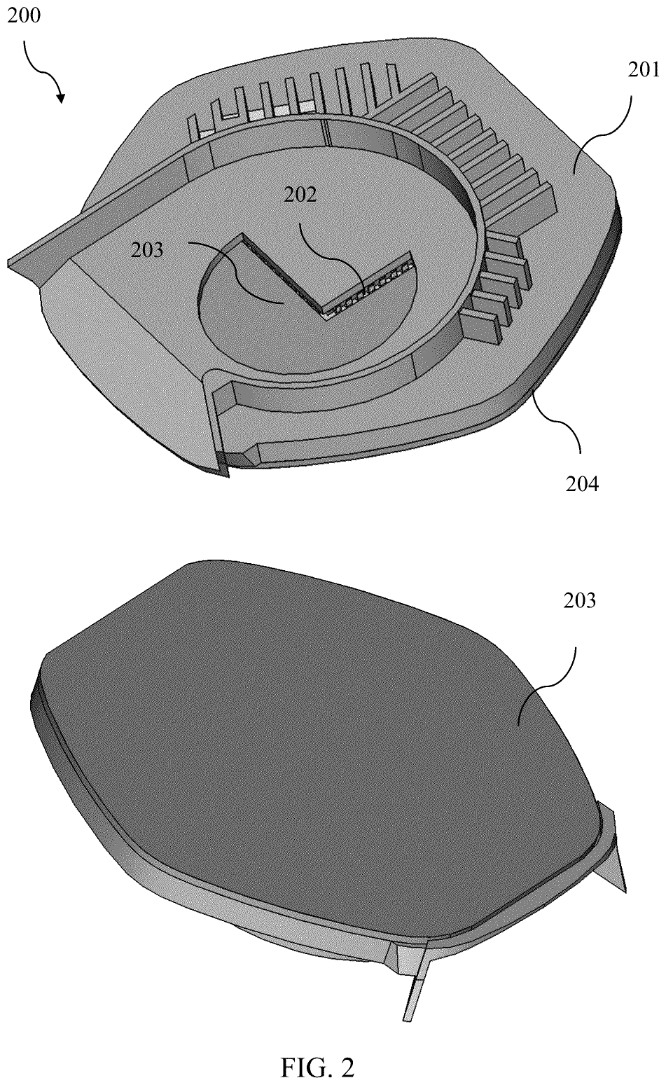

FIG. 2 illustrates an assembled view of the system 200 in accordance with some embodiments. In some embodiments, the system 200 comprises one or more of a heat sink 201, a grounding shield 202, and a printed circuit board 203 (PCB). The heat sink 201 includes a general hexagon perimeter profile 204 in this non-limiting example, but is not limited to any particular shape. Similarly, in some embodiments, the printed circuit board 203 also possesses a general hexagon profile in this example, but any shape may be used. In some embodiments, the heat sink 201 and the printed circuit board 203 comprise a same perimeter profile, ensuring complete protection and heat dissipation for the various PCB components.

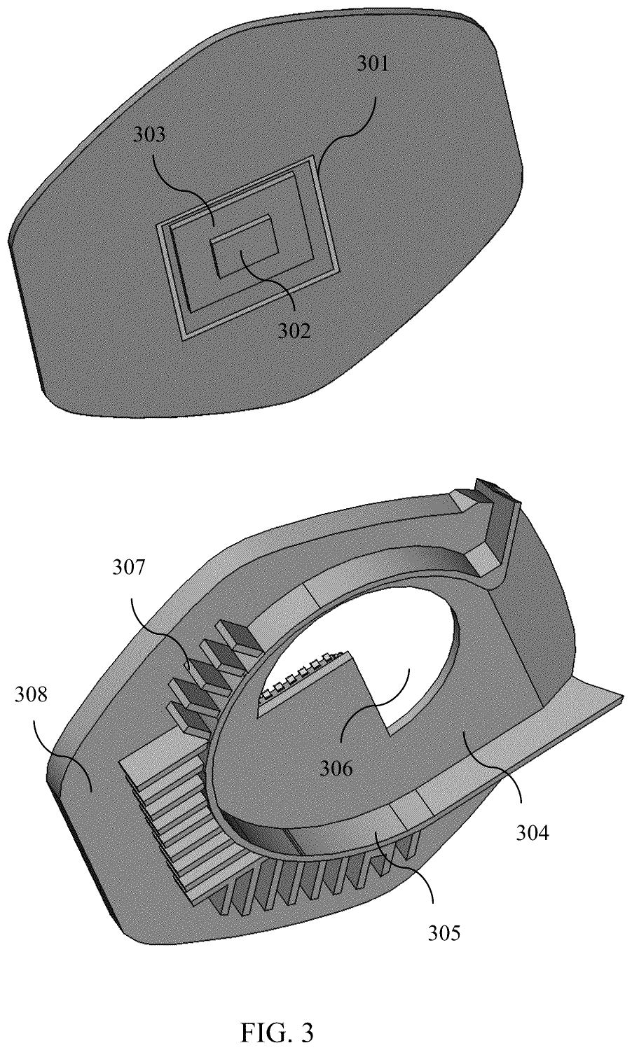

FIG. 3 shows the heat sink 201 separated from the printed circuit board 203 in accordance with some embodiments. In some embodiments, the heat sink 201 is both electrically and thermally conductive, and is configured to remove heat from the printed circuit board 203, central processing unit 302 (CPU) and/or chipset 303. A first side of the heat sink 201, according to some embodiments, comprises a fan mounting area 304, where the fan mounting area 304 includes one or more fan mounting walls 305. In some embodiments, the one or more heat sink fins 307 extend away from the one or more fan mounting walls 305 and/or the fan mounting area 304. The heat sink 201 also includes a fan aperture 306 located within the fan mounting area 304 in some embodiments. In some embodiments, the printed circuit board 203 comprises a grounding track 301, and is configured to attach to a second side 402 of the heat sink 201.

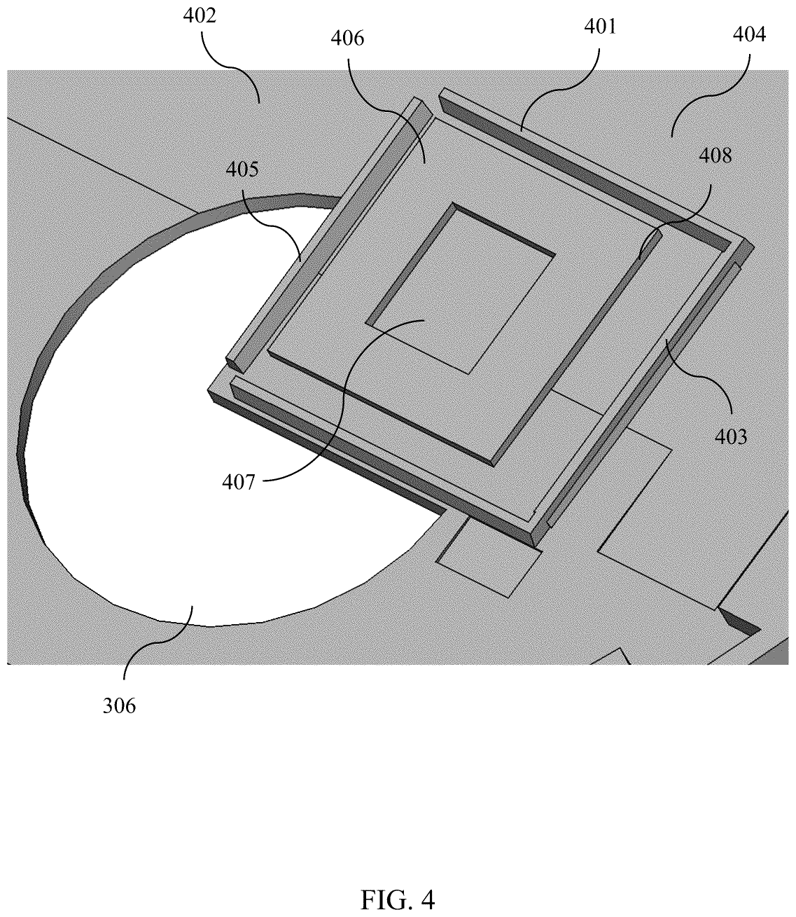

FIG. 4 depicts a second side 402 of the heat sink 201 in accordance with some embodiments. In some embodiments, the heat sink 201 comprises a grounding protrusion 401 located on the second side 402. In some embodiments, the grounding protrusion 401 is configured to align with the grounding track 301 when the heat sink 201 is coupled to the printed circuit board 203. FIG. 4 shows some embodiments of the heat sink 201 that include a fan aperture 306 that enables air to pass from the first side 308 to the second side 402. The grounding protrusion 401, in some embodiments, comprises one or more grounding walls 403 extending from a heat sink surface 404, forming a shielding perimeter 405.

At least a portion of the shielding perimeter 405 forms at least a portion of the fan aperture 306 in some embodiments. The heat sink 201, in some embodiments, includes a sink protrusion 406 within the shielding perimeter 405, which allows for the heat sink 201 surface to be in closer proximity to the chipset 303 and/or CPU. In some embodiments, the sink protrusion 406 includes a thermal pad recess 407. In some embodiments, the thermal pad recess 407 is configured to house and/or surround a thermal pad, and/or to enable a thermal pad 901 to be placed between and/or in contact with the CPU and/or the chipset 303, while at least a portion of the remainder of the sink protrusion 406 extends up to and/or past the thermal pad. Each of the one or more grounding walls 403, in some embodiments, comprise a substantially linear shape, giving a substantially polygonal (e.g., rectangular) shape to the shielding perimeter 405. In some embodiments, a sink perimeter 408 of the sink protrusion 406 and/or a pad perimeter of the thermal pad recess 407 is offset from a center of the shielding perimeter 405, enabling greater airflow in the area of the chipset 303 and/or CPU 302.

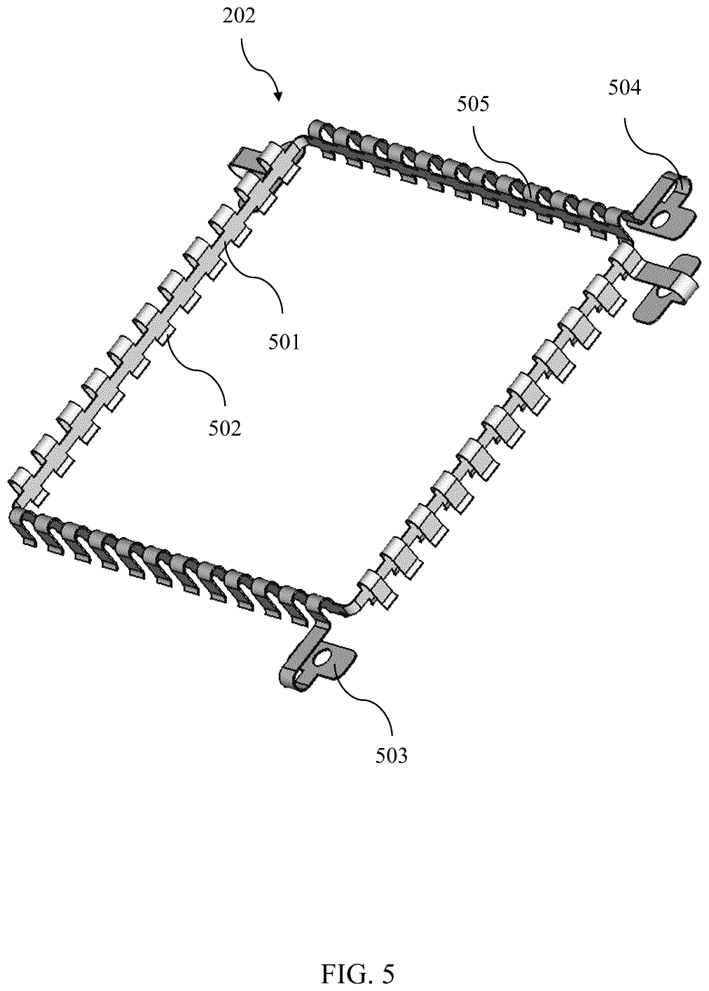

FIG. 5 shows a grounding shield 202 isolated from the rest of the system 200 in accordance with some embodiments. In some embodiments, the grounding shield 202, in conjunction with the heat sink 201, is configured to form a Faraday cage and/or electrical shielding around one or more central processing units 302 and/or one or more chipsets 303. In some embodiments, the electric shielding is configured to protect sensitive electronic components from external electromagnetic interference and/or static discharge that could affect their performance. The grounding shield 202 also provides a layer of physical protection to the electronic components against mechanical damage.

As shown in FIG. 5, in some embodiments, the grounding shield 202 includes a grounding rail 501. The grounding rail 501, in some embodiments, includes a plurality of electrical contacts 502 configured to complete a circuit between the one or more grounding protrusions 401 and the grounding track 301. In some embodiments, the electrical contacts 502 are configured to deform when engaged with a grounding protrusion 401. In some embodiments, one or more of the plurality of electrical contacts 502 comprise a spring clip 505 which enable an open end 701 of an electrical contact 502 to yield to the force of a grounding protrusion 401.

In some embodiments, each of the plurality of electrical contacts 502 are spaced apart from each other along the grounding rail 501. In some embodiments, the grounding shield 202 comprises one or more fasteners 503 configured to secure and/or fix the grounding shield 202 to the heat sink 201. In some embodiments, these fasteners 503 are configured to enable the electrical contacts 502 to move vertically when the one or more fasteners 503 are fixed to the heat sink 201. In some embodiments, the one or more fasteners 503 include a u-shaped profile 504, which allows the ground rail and/or electrical contacts 502 to move along a grounding protrusion 401 draft angle when the one or more fasteners 503 are coupled to the heat sink 201.

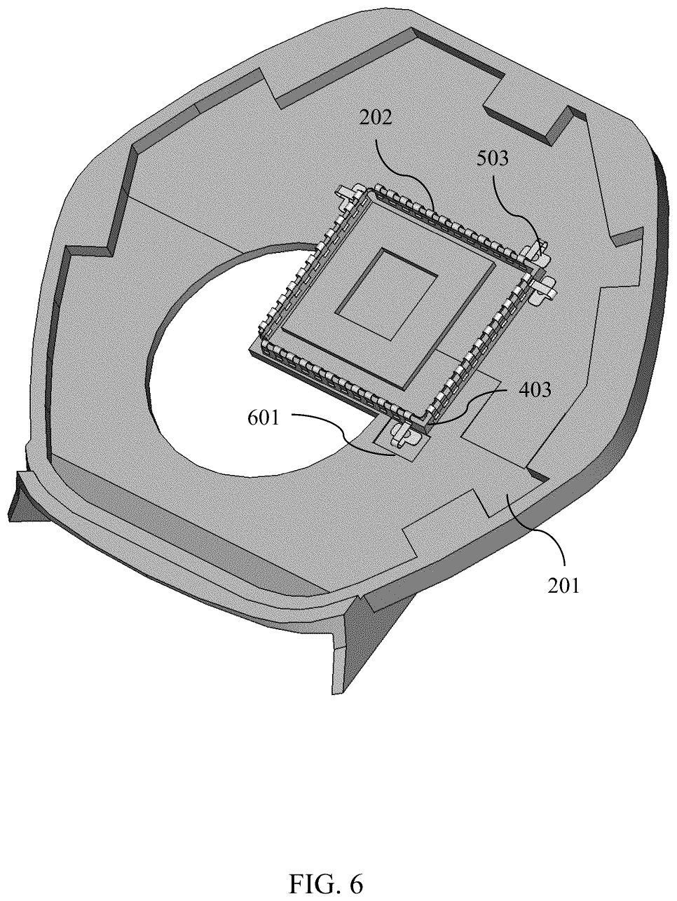

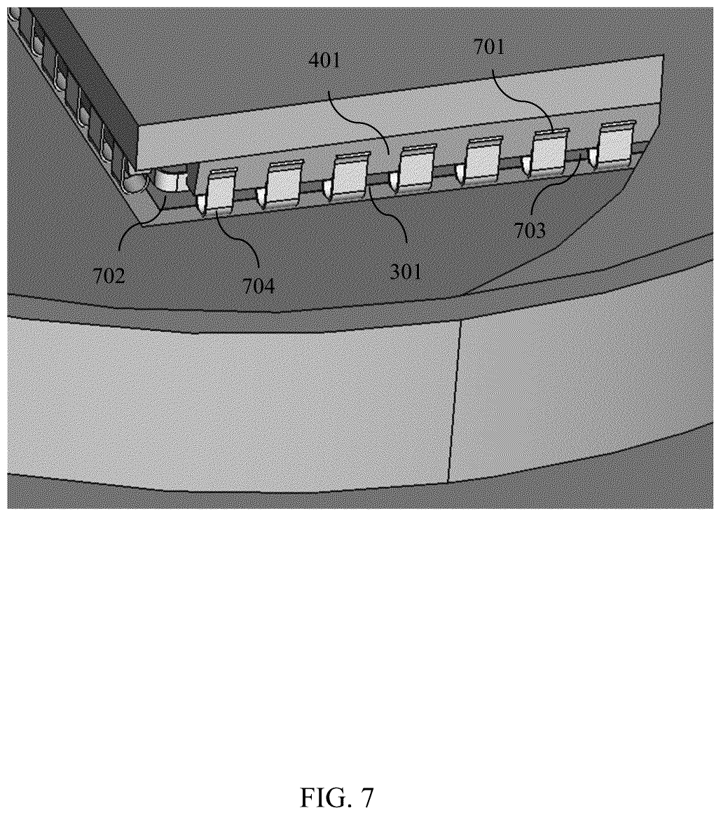

Referring now to FIG. 6, in some embodiments, the heat sink 201 includes a single fan aperture 306 for air flow. In some embodiments, the grounding shield 202 is configured to detachably couple to the grounding protrusion 401 by decoupling the fasteners 503, which improves the manufacturing process by allowing the grounding shield 202 to be manufactured separately. In some embodiments, the open end 701 (best shown in FIG. 7) is configured to receive a grounding wall 403, engage a grounding wall 403, and/or apply a compression spring force to a grounding wall 403. The closed end 703 of the u-shaped profile 504 is configured to contact the grounding track 301 in accordance with some embodiments. In some embodiments, the engagement of the grounding wall 403 with the grounding shield 202 is configured to impart a downward spring force of the grounding shield 202 to the grounding track 301. This again improves the manufacturing process by negating the need to have a rigid connection point between a grounding protrusion 401 and the grounding track 301. In some embodiments, the one or more fasteners 503 are configured to be outside 601 the shielding perimeter 405 of a grounding protrusion 401 when coupled to the heat sink 201.

In some embodiments, as illustrated in FIG. 7, the one or more grounding protrusions 401 are configured not to touch the grounding track 301 when the heat sink 201 is coupled to the printed circuit board 203. Instead, a gap 801 is formed between the grounding protrusion 401 and the grounding track 301 when the heat sink 201 is coupled to the printed circuit board 203. In some embodiments, the grounding shield 202 is configured to electrically couple the grounding protrusion 401 to the grounding track 301 when the heat sink 201 is coupled to the printed circuit board 203. In some embodiments, adjacent ends of one or more grounding walls 403 are separated by a gap 702 which further improves airflow. In some embodiments, the spacing 704 between each of the electrical contacts 502 is configured to enable airflow from the fan aperture 306 to pass through, further improving efficiency of the system 200. In some embodiments, by using the draft angle on two sides of a grounding wall, a push down force is created, pushing the electrical contact down against the grounding track 301, further improving electrical contact. In some embodiments, the u-shaped profile 504 against the draft angle of a grounding protrusion 401 creates a compressive force against both side of a grounding protection.

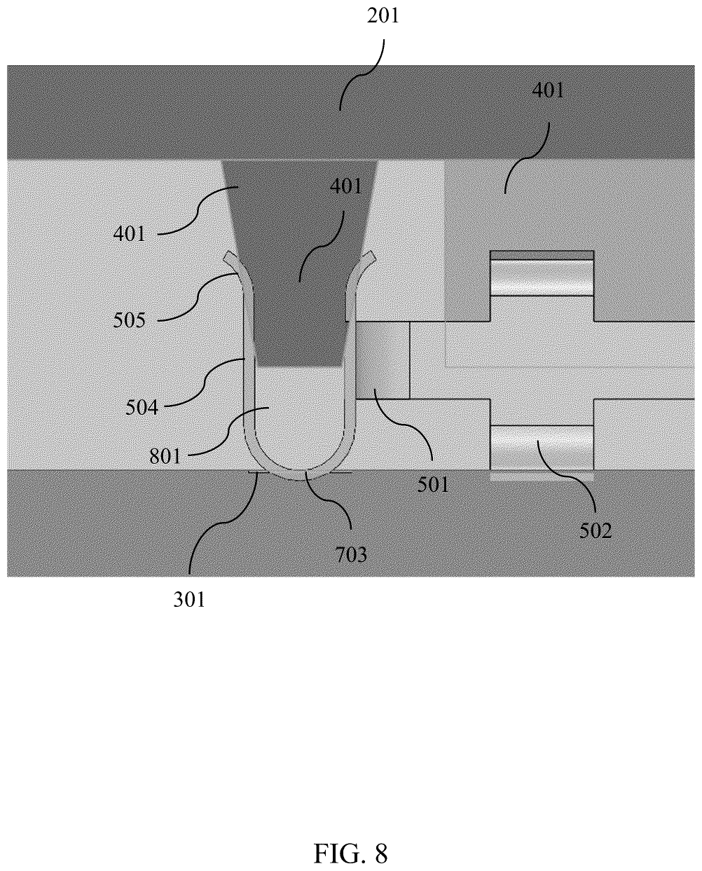

FIG. 8 shows a sectional view of the system 200 according to some embodiments. In some embodiments, the u-shaped profile 504 comprises an open end 701 and a closed end 703, forming a general u-shaped profile for each spring clip 505. In some embodiments, the grounding shield 202 is configured to transfer heat generated from one or more of the printed circuit board 203, the chipset 303, the central processing unit 302, the one or more electrical contacts, and/or air, to the heat sink 201.

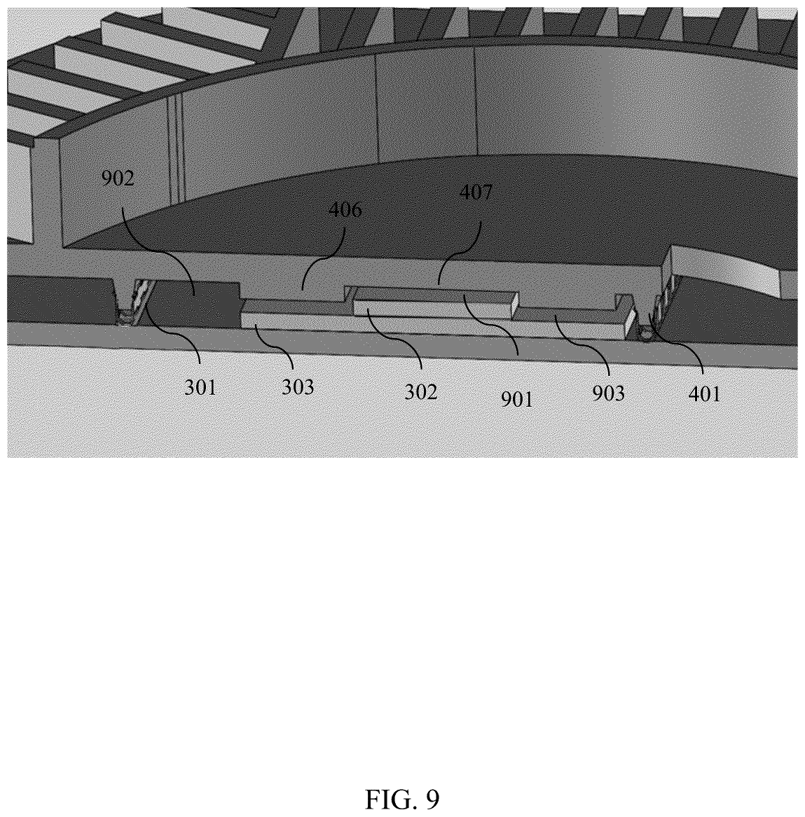

FIG. 9 shows an isometric sectional view of the assembled system 200 according to some embodiments. In some embodiments, the grounding protrusion 401 is configured to surround the central processing unit 302 and/or a chipset 303, protecting it from foreign objects and/or forming the electrical shield as previously described, while also providing an air flow area 902 between the heat sink 201 and the PCB 203. In some embodiments, the one or more grounding walls 403 are configured to form a shielding perimeter 405 around the central processing unit 302 and/or a chipset 303, where the shielding perimeter 405 may or may not have one or more gaps. As shown in FIG. 9, each of the one or more grounding walls 403 is configured to protect a side of a central processing unit 302 and/or a chipset 303. In some embodiments, the sink protrusion 406 is configured to cover an area defined by a perimeter of the central processing unit 302 and/or chipset 303. In some embodiments, the sink protrusion 406 includes a gap 903, and/or is configured not to contact the central processing unit 302 and/or chipset 303, which mitigates the possibility electrical shorts.

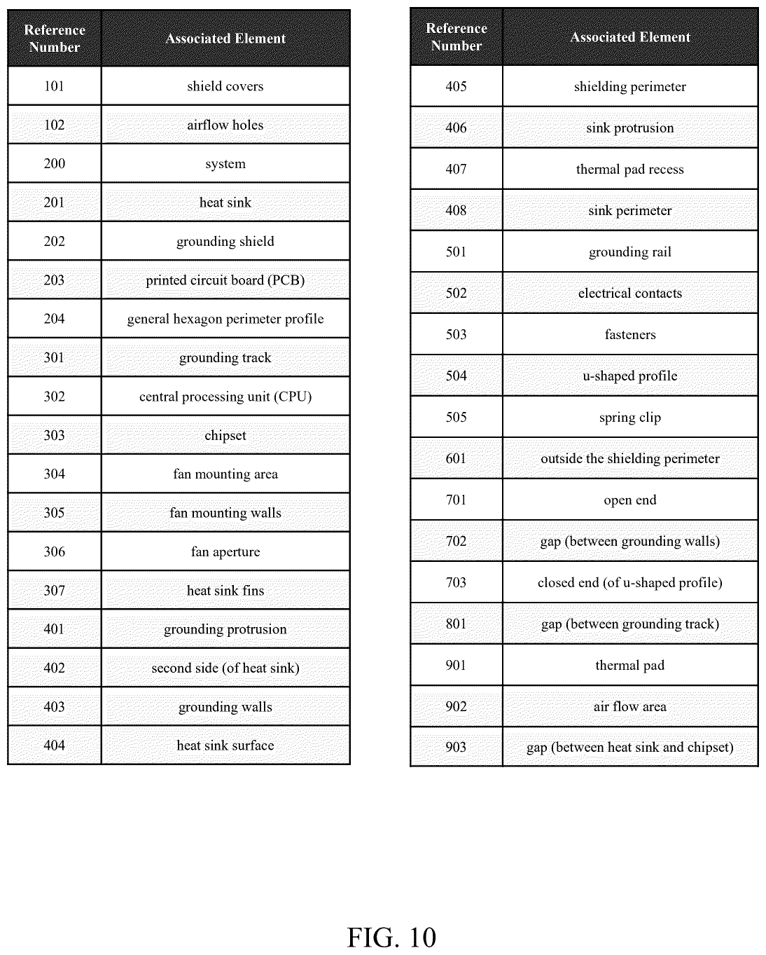

FIG. 10 shows a reference number table for elements of the system. As outlined above, the combination of the printed circuit board, the grounding shield, and/or the heat sink forms a system that is configured to both protect the central processing unit and/or chipset from physical damage, and provide an electrical shield, and/or provide a ground for the printed circuit board. However, it is understood that the system is not limited in its application to the details of construction and the arrangement of components set forth in the previous description or illustrated in the drawings. The system and methods of assembly disclosed herein fall within the scope of numerous embodiments. The previous discussion is presented to enable a person skilled in the art to make and use embodiments of the system. Any portion of the structures and/or principles included in some embodiments can be applied to any and/or all embodiments: it is understood that features from some embodiments presented herein are combinable with other features according to some other embodiments. Thus, some embodiments of the system are not intended to be limited to what is illustrated but are to be accorded the widest scope consistent with all principles and features disclosed herein.

Some embodiments of the system are presented with specific values and/or setpoints. These values and setpoints are not intended to be limiting and are merely examples of a higher configuration versus a lower configuration and are intended as an aid for those of ordinary skill to make and use the system.

Any text in the drawings is part of the system's disclosure and is understood to be readily incorporable into a description of the metes and bounds of the system. Any functional language in the drawings is a reference to the system being configured to perform the recited function, and structures shown or described in the drawings are to be considered as the system comprising the structures recited therein. It is understood that defining the metes and bounds of the system using a description of images in the drawing does not need a corresponding text description in the written specification to fall with the scope of the disclosure.

Furthermore, acting as Applicant's own lexicographer, Applicant imparts the explicit meaning and/or disavow of claim scope to the following terms:

Applicant defines any use of “and/or” such as, for example, “A and/or B,” or “at least one of A and/or B” to mean element A alone, element B alone, or elements A and B together. In addition, a recitation of “at least one of A, B, and C,” a recitation of “at least one of A, B, or C,” or a recitation of “at least one of A, B, or C or any combination thereof” are each defined to mean element A alone, element B alone, element C alone, or any combination of elements A, B and C, such as AB, AC, BC, or ABC, for example.

“Substantially” and “approximately” when used in conjunction with a value encompass a difference of 5% or less of the same unit and/or scale of that being measured (e.g., degrees, volume, mass, distance).

As used herein, “can” or “may” or derivations thereof are used for descriptive purposes only and is understood to be synonymous and/or interchangeable with “configured to” when defining the metes and bounds of the system.

In addition, the term “configured to” means that the limitations recited in the specification and/or the claims must be arranged in such a way to perform the recited function: “configured to” excludes structures in the art that are “capable of” being modified to perform the recited function but the disclosures associated with the art have no explicit teachings to do so. For example, a recitation of a “container configured to receive a fluid from structure X at an upper portion and deliver fluid from a lower portion to structure Y” is limited to systems where structure X, structure Y, and the container are all disclosed as arranged to perform the recited function. The recitation “configured to” excludes elements that may be “capable of” performing the recited function simply by virtue of their construction but associated disclosures (or lack thereof) provide no teachings to make such a modification to meet the functional limitations between all structures recited.

It is understood that the phraseology and terminology used herein is for description and should not be regarded as limiting. The use of “including,” “comprising,” or “having” and variations thereof herein is meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

The previous detailed description is to be read with reference to the figures, in which like elements in different figures have like reference numerals. The figures, which are not necessarily to scale, depict some embodiments and are not intended to limit the scope of embodiments of the system.

It will be appreciated by those skilled in the art that while the system has been described above in connection with some embodiments and examples, the system is not necessarily so limited, and that numerous other embodiments, examples, uses, modifications and departures from the embodiments, examples and uses are intended to be encompassed by the claims attached hereto. The entire disclosure of each patent and publication cited herein is incorporated by reference, as if each such patent or publication were individually incorporated by reference herein. Various features and advantages of the system are set forth in the following claims.

What is claimed is:

1. A system comprising:
a heat sink,
a grounding shield, and
a printed circuit board;
wherein the heat sink comprises one or more grounding protrusions;
wherein the printed circuit board comprises one or more grounding tracks;
wherein the one or more grounding protrusions are configured to align with at least a portion of the one or more grounding tracks when the heat sink is coupled to the printed circuit board; and
wherein the grounding shield is configured to create an electrical coupling between the one or more grounding protrusions and the one or more grounding tracks when the heat sink is coupled to the printed circuit board.

2. The system of claim 1,
wherein the printed circuit board comprises one or more central processing units and/or one or more chipsets;
wherein the one or more grounding protrusions are configured to form a shielding perimeter around the one or more central processing units and/or the one or more chipsets.

3. The system of claim 2,
wherein the grounding shield is configured to surround the one or more central processing units and/or the one or more chipsets along the shielding perimeter.

4. The system of claim 3,
wherein a combination of the heat sink, the grounding shield, and the one or more grounding protrusions is configured to form a Faraday cage around the one or more central processing units and/or the one or more chipsets.

5. The system of claim 1,
wherein the grounding shield comprises a grounding rail.

6. The system of claim 5,
wherein the grounding rail comprises a plurality of electrical contacts.

7. The system of claim 6,
wherein each of the plurality of electrical contacts are configured to deform when engaged with the one or more grounding protrusions.

8. The system of claim 6,
wherein each of the plurality of electrical contacts are spaced apart from each other to form spacings along the grounding rail.

9. The system of claim 6,
wherein one or more of the plurality of electrical contacts comprise a spring clip.

10. The system of claim 9,
wherein the spring clip comprises a substantially u-shaped profile.

11. The system of claim 1,
wherein the grounding shield comprises one or more fasteners configured to secure and/or fix the grounding shield to the heat sink.

12. The system of claim 11,
wherein the one or more fasteners are configured to enable electrical contacts to move relative to the one or more grounding protrusions when the one or more fasteners are fixed to the heat sink.

13. The system of claim 2,
wherein the heat sink comprises a fan aperture.

14. The system of claim 13,
wherein at least a portion of the shielding perimeter forms at least a portion of the fan aperture.

15. The system of claim 8,
wherein the heat sink comprises a fan aperture; and
wherein the spacings between each of the plurality of electrical contacts is configured to enable airflow from the fan aperture to pass through.

16. A method of creating an electrical shield around one or more central processing units and/or one or more chipsets comprising steps of:
providing a heat sink, a printed circuit board, and a grounding shield;
coupling the grounding shield to the heat sink; and
coupling the grounding shield to the printed circuit board.

17. The method of claim 16, further including a step of:
using the grounding shield in conjunction with the heat sink and a grounding track on the printed circuit board to form a Faraday cage and/or electrical shielding around the one or more central processing units and/or the one or more chipsets.

18. The method of claim 16, further including a step of:
configuring at least a portion of the grounding shield to be able to move relative to the heat sink when the grounding shield is coupled to the heat sink.

19. The method of claim 16, further including steps of:
providing one or more grounding protrusions extending from a surface of the heat sink toward the printed circuit board when the heat sink, the grounding shield, and the printed circuit board are assembled together; and
providing a gap between the one or more grounding protrusions and the printed circuit board when the heat sink, the grounding shield, and the printed circuit board are assembled together.

20. The method of claim 19, further including a step of:
configuring the grounding shield to electrically bridge the gap between the one or more grounding protrusions and the printed circuit board when the heat sink, the grounding shield, and the printed circuit board are assembled together.
